(19) United States
(12) Patent Application Publication
(10) Pub. No.: US 2014/0368268 A1
(43) Pub. Date: Dec. 18, 2014

(54) Load Tuning Circuit For Pulse-Width / Pulse-Position Modulation Amplifier And Related Techniques

(71) Applicant: Auriga Measurement Systems, LLC, Chelmsford, MA (US)

(72) Inventors: Yusuke Tajima, Acton, MA (US); John Muir, North Chelmsford, MA (US)

(73) Assignee: AURIGA MEASUREMENT SYSTEMS, LLC, Chelmsford, MA (US)

(21) Appl. No.: 14/308,058

(22) Filed: Jun. 18, 2014

Related U.S. Application Data
(60) Provisional application No. 61/836,237, filed on Jun. 18, 2013.

(51) Int. Cl. H03F 1/02; H03F 3/20; H03F 3/189

(52) U.S. Cl. CPC H03F 1/02; H03F 3/189; H03F 3/20
USPC 330/192

(57) ABSTRACT

A pulse width modulated/pulse modulated PWM/PPM power amplification circuit includes a load modulation circuit coupled between an output of the amplification circuit and a load. In one embodiment, the load modulation circuit comprises a plurality of capacitor elements switchably coupled such that in response to a control signal provided the load modulation circuit presents one of a plurality of different capacitance values at a terminal thereof. By changing capacitance values associated with the plurality of capacitor elements in accordance with the output of the amplification circuit and the load, improved (and “optimum”) power levels that exhibit a desired (and best) efficiency can be selected. Such results in an amplification circuit having an efficiency level which is relatively high compare with efficiency levels of conventional amplifier circuits over a wide dynamic range of output power.

### CROSS REFERENCE TO RELATED APPLICATIONS

The present application claims the benefit of U.S. Provisional Application No. 61/836,237, filed on Jun. 18, 2013, which is hereby incorporated by reference herein in its entirety.

### STATEMENT REGARDING FEDERALLY SPONSORED RESEARCH

Not Applicable.

### FIELD

This disclosure relates generally to radio frequency (RF) circuits and, more particularly, to techniques and circuits for operation of RF amplifier circuits.

### BACKGROUND

As is known in the art, radio frequency (RF) transmit systems (such as those found in cellular phone and satellite communication systems) commonly employ RF amplifying devices such as an RF power amplifier (RF PA). RF PA's typically receive input signals (e.g., modulated signals) from a source (e.g., modulator circuitry in RF transmit system) and transfer the input signals in the form of an RF output signal to a load (e.g., antenna) coupled to an output of the RF PA. If the load is an antenna, for example, the RF output signal is emitted into free space or some other transmission medium.

As is also known, RF PA performance is affected not only by factors related to component tolerances and fabrication techniques (e.g. tolerances associated with fabrication techniques such as semiconductor fabrication techniques), but is likewise influenced by factors such as the input and output impedances associated with circuitry and connections external to the RF PA. For example, impedance matching between the RF PA output and the load input determines, at least in part, how efficiently an RF PA delivers an RF output signal to a load (and how efficiently the RF transmit system transmits the transmitted signal). RF PA output impedance generally varies in response to input signal power levels (Pᵢₙ) provided to an input of the RF PA from a source. Such impedance variations can result in impedance mismatches between the output of the RF PA output and a load coupled thereto. Such can give rise to RF PA inefficiencies and variations in output power (Pₒᵤₜ) delivered to the load.

While conventional techniques for improving RF PA efficiencies (and impedance matching between an RF PA output and a load input) have been somewhat effective, such techniques have typically utilized relatively complicated circuits and techniques with large associated losses which negate the effect of adjustable matching.

### SUMMARY

Described herein is a radio frequency power amplifier circuit (RF PA) and associated techniques for improving RF PA efficiencies. In accordance with the concepts, systems, circuits, and techniques described herein, in one aspect a pulse width modulated/pulse position modulated (PWM/PPM) amplification circuit comprises a load modulation circuit coupled between an output of the amplification circuit and a load.

With this particular arrangement, a circuit capable of modulating load impedance to maintain high efficiency over a wide range of output power is provided. In one example embodiment, the load modulation circuit comprises a transmission line and a capacitor circuit shunt coupled between the transmission line and a reference potential. In one embodiment, the capacitor circuit comprises at least one capacitor having a first terminal coupled to one end of said transmission line and a second terminal couple to the reference potential. In one embodiment, the reference potential is ground.

In another example embodiment, the load modulation circuit comprises a plurality of capacitor elements switchably coupled such that in response to a control signal provided thereto, the load modulation circuit presents one of a plurality of different capacitance values at a terminal thereof. In one embodiment, the capacitor circuit is provided as a variable capacitor having a capacitance value which changes in response to the control signal.

In another example embodiment, the load modulation circuit comprises a plurality of series capacitors switchably coupled between the output of the amplification circuit and a load, and a plurality of shunt inductors switchably coupled from the output of the amplification circuit to ground. In one embodiment, the inductors are implemented with transmission lines. In one embodiment, the transmission lines are disposed on or between one or more substrates and inductance values are achieved by varying one or more of transmission line widths and substrate thicknesses. Other techniques may also be used. In another embodiment, the plurality of series capacitors are implemented with a single variable capacitor having a capacitance value which changes in response to a control signal.

In another aspect, an amplifier circuit having an input and an output includes a pulse generator circuit having an input adapted to couple to the amplifier circuit input. The pulse generator circuit is configured to receive a representative amplifier input signal at the pulse generator circuit input. In one aspect, the pulse generator circuit is substantially capable of implementing a pulse width modulation (PWM) scheme or a pulse position modulation (PPM) scheme and providing appropriately modulated analog signals at an output thereof. In one embodiment, the pulse generator circuit includes a digital to analog converter (DAC). The amplifier circuit further includes a driver amplification circuit having an input coupled to the output of the pulse generator circuit.

In the one aspect, the amplifier circuit also includes an output amplification circuit having an input coupled to the output of the driver amplification circuit and having an output. The amplifier circuit additionally includes a reconstruction filter having an input coupled to the output of said output amplification circuit and having an output coupled to the output of the amplifying circuit. The reconstruction filter removes the harmonic content of the signal associated with the pulse shaped signal. The output from the filter should contain only the signal components without harmonics. The amplifier circuit further includes a load modulation circuit coupled between the output of the reconstruction filter and the output of the amplifying circuit. The load modulation circuit has a selectable capacitance values which are selected such that the amplifier circuit is capable of operation at over a wide range of power levels while exhibiting a desired efficiency over a wide dynamic range of output powers.

In one example embodiment, the load modulation circuit comprises a transmission line and a capacitor circuit shunt coupled between the transmission line and a reference potential. In one embodiment, the capacitor circuit comprises at least one capacitor having a first terminal coupled to one end of said transmission line and a second terminal couple to ground. In another embodiment, the capacitor circuit comprises one or more capacitors with at least one of the capacitors having a terminal electrically coupled to a portion of the transmission this and at least one capacitor having a terminal electrically coupled to ground.

In another example embodiment, the load modulation circuit comprises a plurality of capacitor elements switchably coupled such that in response to a control signal provided said load modulation circuit presents one of a plurality of different capacitance values at a terminal thereof. In one embodiment, the capacitor circuit is provided as a variable capacitor capable having a capacitance value which changes in response to a control signal.

In one embodiment, the driver amplification circuit comprises a radio frequency (RF) amplifier having relatively high gain characteristics. In another embodiment, the output amplification circuit comprises an RF power amplifier (PA) having a relatively high power characteristic.

In another aspect, a method of operating a power amplification circuit includes coupling a load modulation circuit comprising one or more tuning elements between an output of the power amplification circuit and a load. The method additionally includes adjusting at least some of the one or more tuning elements such that the power amplifier circuit is capable of operating at power levels that exhibit a desired efficiency over a wide dynamic range of output powers. In one embodiment, adjusting at least some of the one or more tuning elements comprises matching an output impedance associated with the power amplification circuit to an input impedance associated with the load.

### BRIEF DESCRIPTION OF THE DRAWINGS

The foregoing features of the disclosure, as well as the disclosure itself may be more fully understood from the following detailed description of the drawings, in which:

FIG. 1 is a block diagram of an example radio frequency (RF) amplifier circuit;

FIG. 2 is a plot of drain efficiency versus output power (Pₒᵤₜ) for an RF amplifier circuit which may be the same as or similar to the RF amplifier circuit of FIG. 1;

FIG. 3 is a schematic diagram illustrating an example RF amplifier circuit in accordance with an embodiment;

FIG. 4 is a plot of drain efficiency versus Pₒᵤₜ for an RF amplifier circuit of the type shown in FIG. 3; and

FIG. 5 is a plot of drain efficiency and Pₒᵤₜ versus frequency for an RF amplifier circuit of the type shown in FIG. 3.

### DETAILED DESCRIPTION

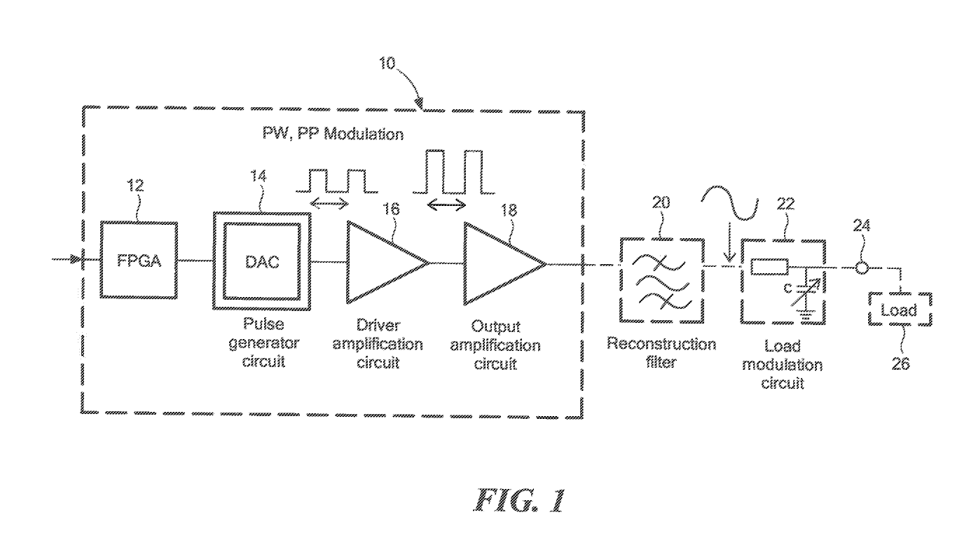

The features and other details of the concepts, systems, circuits and techniques sought to be protected herein will now be more particularly described. It will be understood that any specific embodiments described herein are shown by way of illustration and not as limitations of the disclosure. The principal features of this disclosure can be employed in various embodiments without departing from the scope of the concepts sought to be protected. The preferred embodiments of the present disclosure and associated advantages are best understood by referring to FIGS. 1-5 of the drawings, like numerals being used for like and corresponding parts throughout the various drawings.

### DEFINITIONS

For convenience, certain introductory concepts and terms used in the specification are collected here.

As used herein, the term “processor” is used to describe an electronic circuit that performs a function, an operation, or a sequence of operations. The function, operation, or sequence of operations can be hard coded into the electronic circuit or soft coded by way of instructions held in a memory device. A “processor” can perform the function, operation, or sequence of operations using digital values or using analog signals.

In some embodiments, the “processor” can be embodied, for example, in a specially programmed microprocessor, a digital signal processor (DSP), or an application specific integrated circuit (ASIC), which can be an analog ASIC or a digital ASIC. In some embodiments, the “processor” can be embodied in a microprocessor with associated program memory. In some embodiments, the “processor” can be embodied in a discrete electronic circuit, which can be an analog or digital.

Referring now to FIG. 1, an amplifier circuit 10 includes a processor 12 (here shown as a field programmable gate array (FPGA) in the example embodiment of FIG. 1), a pulse generator circuit 14, a driver amplification circuit 16, an output amplification circuit 18, a reconstruction filter 20, a load modulation circuit 22 and a load 26 coupled as shown, The amplifier circuit 10 may be configured to amplify radio frequency (SF) signals and be included as part of or coupled to RF transmit system circuitry (not shown), but it is not so limited. In this example embodiment, the reconstruction filter 20, load modulation circuit 22 and load 26 (e.g., antenna) are not properly a part of the amplifier circuit 10 and thus are shown in phantom lines in FIG. 1. It should, of course, be appreciated that in other embodiments the amplifier circuit 10, the reconstruction Mer 20, load modulation circuit 22 and load 26 may be provided within a single circuit (e.g., a single integrated circuit). It should also be appreciated that the functionality provided by each of the amplifier circuit 10, reconstruction filter 20, load modulation circuit 22 and load 26 may be shared or split in a manner other than as illustrated in FIG. 1.

The amplifier circuit 10 receives amplifier input signals (e.g., modulated signals) at an input adapted to couple to circuitry (e.g., source circuitry of RF transmit system circuitry) for providing the amplifier input signals. The amplifier input signals can, for example, be received in either digital or analog form and typically have an associated input power (Pᵢₙ). The processor 12 receives the amplifier input signals at an input adapted to couple to an input of the amplifier circuit 10. The processor 12, in response thereto, provides an associated digital signal to an input of a pulse generator circuit 14 coupled to an output of the processor 12 (e.g., an output pin). The pulse generator circuit 14, which includes a digital to analog converter (DAC) in the example embodiment shown, receives the associated digital signal (or a representative amplifier input signal) and in response thereto applies a pulse width modulation (PWM) scheme and/or a pulse position modulation (PPM) scheme to the associated digital signal to produce a pulsed signal at an output thereof. In one embodiment, the pulse generator circuit 14 is implemented within the processor 12 using high-speed digital transceiver technology, if the processor 12 is capable of generating high speed pulses without degrading the pulse characteristics. The high-speed digital transceiver includes the serializer-deserializer (SERDES) and supporting technology to achieve high data rates.

The driver amplification circuit 18 (or more simply, a “driver stage”) has an input coupled to the output of the pulse generator circuit 14. The driver stage 16 which may, for example, comprise an amplifier circuit having a relatively high gain characteristic, receives the pulsed signal and in response thereto generates a driver signal at an output thereof. The gain of the driver stage 16 will have to be large enough to amplify the incoming pulses and generate the driver signal such that the driver signal is capable of driving the power stage output amplification circuit 18) into saturation.

The output amplification circuit 18 (or more simply, an “output stage”), which includes a power amplifier (PA) in the example embodiment shown, has an input coupled to the output of driver stage 16. The output stage 18 receives the driver signal and in response thereto generates amplifier output signals having required power and signal characteristics for the system at an output thereof. The amplifier output signals have an associated output power (Pₒᵤₜ). In one embodiment, the output of output stage 18 forms the output of the amplifier circuit 10.

The reconstruction filter 20 has an input coupled to the output of output stage 18 (or amplifier circuit output). The reconstruction filter 20, which can be provided as an active or passive filter, receives the output signals and in response thereto removes the harmonic components at an output thereof.

The load modulation circuit 22 (also sometimes referred to herein as a “tuning element”) has an input coupled to the output of the reconstruction filter 20. The load modulation circuit 22 receives the appropriately reconstructed signals and modulates the load terminating impedance conditions depending on the reconstructed signal levels. In the embodiment shown, the load modulation circuit is coupled to an output pin (or output port) 24.

In one embodiment, the load modulation circuit 22 is provided from a transmission line having a first end coupled to the reconstruction filter output and a second end coupled to the amplifier circuit output (or output stage output) and a capacitor C shunt coupled between the transmission line and a reference potential (i.e., to redirect high-frequency noise to the reference potential before it can propagate to the load or other circuit components). The reference potential is here shown as ground, but it is not so limited. It should be appreciated that load modulation circuit 22 may comprise one or more capacitors or inductors that can be switched in or out by a control signal (not shown) to provide the load modulation circuit 22 with selectable capacitance and/or inductance. In one embodiment, for example, the load modulation circuit 22 comprises a variable capacitor (or tunable capacitor) having a capacitance value which changes in response to a control signal. The control signal may, for example, be provided by processor 12, but it is not so limited.

In another example embodiment, the load modulation circuit 22 is provided from a transmission line series coupled between the reconstruction filter output and an output port 24 coupled to the load 26 (e.g., an antenna) and a variable capacitor shunt coupled between the transmission line and a reference potential (e.g., ground). In one embodiment, the capacitance value of the capacitor C is selected to achieve an amplifier output signal with a desired power level (Pₒᵤₜ) (also sometimes referred to herein as an “output power”) and/or drain efficiency (power ratio of amplifier output signal to input signal, Pₒᵤₜ/Pᵢₙ). In another embodiment, the capacitor C is selected such that an output impedance associated with amplifier circuit 10 substantially matches an input impedance associated with load 26. As a result, the amplifier circuit 10 is substantially capable of achieving an efficiency level which is relatively high compared with efficiency levels of conventional amplifier circuits over a wide dynamic range of output power (Pₒᵤₜ). Compared to a fixed load impedance amplifier, the efficiency at the back-off of the amplifier circuit 10 can be more than 2:1 when the load impedance is tuned with this embodiment.

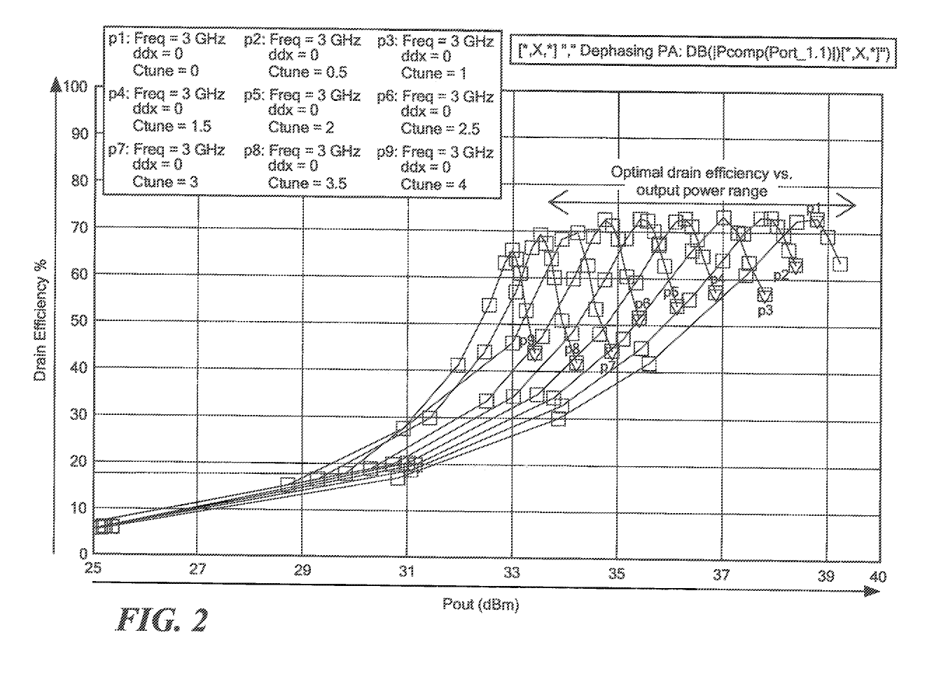

Thus, as described above, the amplifier circuit 10 includes a load modulation circuit 22 (or tuning element) adapted to couple to an output of the amplifier circuit 10, here shown through reconstruction filter 20, but it is not so limited. Such results in the amplifier circuit 10 being capable of modulating the load 26 (i.e., input impedance of the load 2) so as to maintain a high efficiency level over a wide range of output power (Pₒᵤₜ) as will be explained in conjunction with FIG. 2.

In an alternate embodiment, output stage 18 is capable of generating the appropriately reconstructed signals. In such embodiment, the reconstruction filter 20 may not be needed in or coupled to amplifier circuit 10 and thus the coupling described above is adjusted accordingly.

It is to be appreciated that although processor 12, pulse generator circuit 14, driver stage 16, output stage 18, reconstruction filter 20, load modulation circuit 22 and load 26 are shown coupled in a particular manner, processor 12, pulse generator circuit 14, driver stage 16, output stage 18, reconstruction filter 20, load modulation circuit 22 and load 26 may be coupled directly or through one or more intervening elements.

Additional aspects of the concepts, systems, circuits and techniques described herein will be apparent from the subsequent figures.

Referring now to FIG. 2 a plot of amplifier drain efficiency (Pₒᵤₜ/Pᵢₙ) versus output power (Pₒᵤₜ) has a horizontal axis with a scale in units of decibel-milliwatts (dBm) and a vertical axis with a scale in efficiency units of percent (%). A group of curves shows the difference in the output power where the peak efficiency is achieved when the tuning capacitor C is varied from 0 to 4 pF with 0.5 pF interval. If the C is not varied and kept at 0, the maximum power of 39 dBm is achieved at 70% efficiency. However, when the power is lowered to 33 dBm, the efficiency is only at 27%. If the capacitor value is changed to 4 pF, efficiency at 33 dBm will increase to 69%, 2.5 times improvement. The horizontal axis is representative of power levels of output signals (Pₒᵤₜ) (generated by an amplifier circuit, for example, which can be the same as or similar to amplifier circuit 10 of FIG. 1) in accordance with particular capacitance values (associated with a load modulation circuit, for example, which can be the same as or similar to load modulation circuit 22 of FIG. 1). Various drain efficiencies are shown achieved for particular output powers (Pₒᵤₜ) by changing capacitance values.

As illustrated, a substantially high drain efficiency (approximately 80 percent) can be achieved over a relatively wide range of output power (Pₒᵤₜ) levels (approximately 34 dBm to 39 dBm), as denoted the bi-directional arrow in the figure, by adjusting the capacitance value (i.e. via the load modulation circuit 22 of FIG. 1). Such can produce certain advantages, including longer operation of an RF amplifier circuit on a single battery charge in contrast with conventional amplifier circuits with lower drain efficiency levels, for example, as will be apparent. RF amplifier circuits comprising low drain efficiency levels generally have high levels of heat dissipation, which is undesirable for reasons apparent.

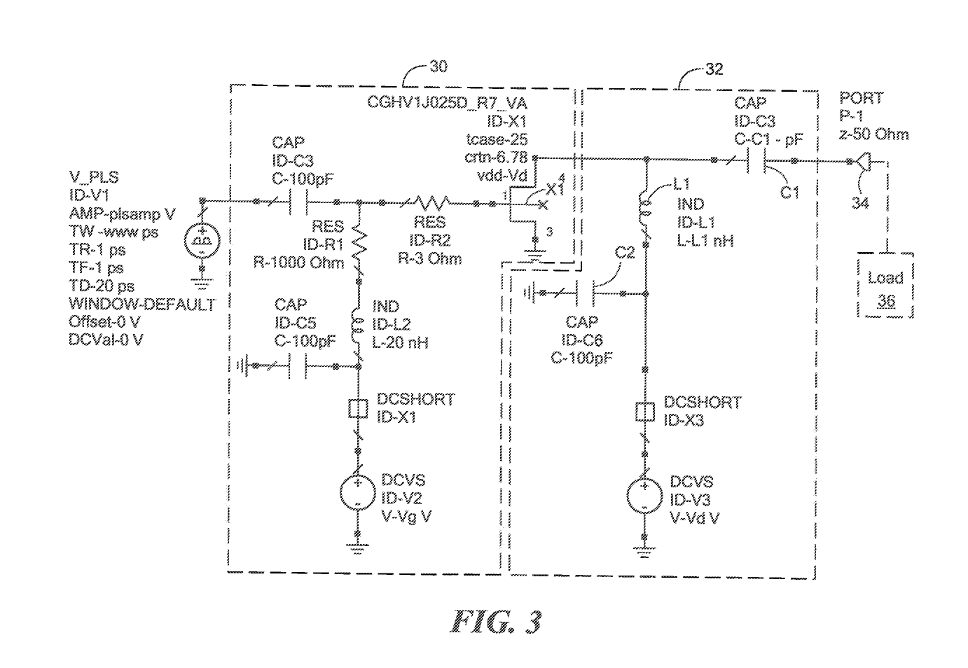

Referring now to FIG. 3, a portion of an RF amplifier circuit 30 is shown coupled to a load modulation circuit 32 comprising a plurality of tuning elements (L1, C1, C2) coupled as shown. The load modulation circuit 32 is coupled to an output port 34 (which can be an output of the load modulation circuit 32) and a load 36 (e.g., antenna). In this example embodiment, the RF amplifier circuit 30 is provided as a parallel circuit Class E amplifier designed for PWM-PPM operation, which receives amplifier input signals (e.g., modulated signals) at an input adapted to couple to circuitry (e.g., source circuitry of RF transmit system circuitry) for providing the amplifier input signals. The tuning elements, here an inductor L1 and capacitors C1, C2, are adjusted in accordance with an output impedance associated with three terminal device X1 (e.g., non transistor) of the RF amplifier circuit to achieve a desired output power (Pₒᵤₜ) and/or drain efficiency (Pₒᵤₜ/Pᵢₙ). The tuning elements can, for example, be adjusted to match the output impedance associated with the three terminal device X1 with an input impedance associated with the load 36. In one embodiment, en output of the three terminal device forms an output of RF amplification circuit 30.

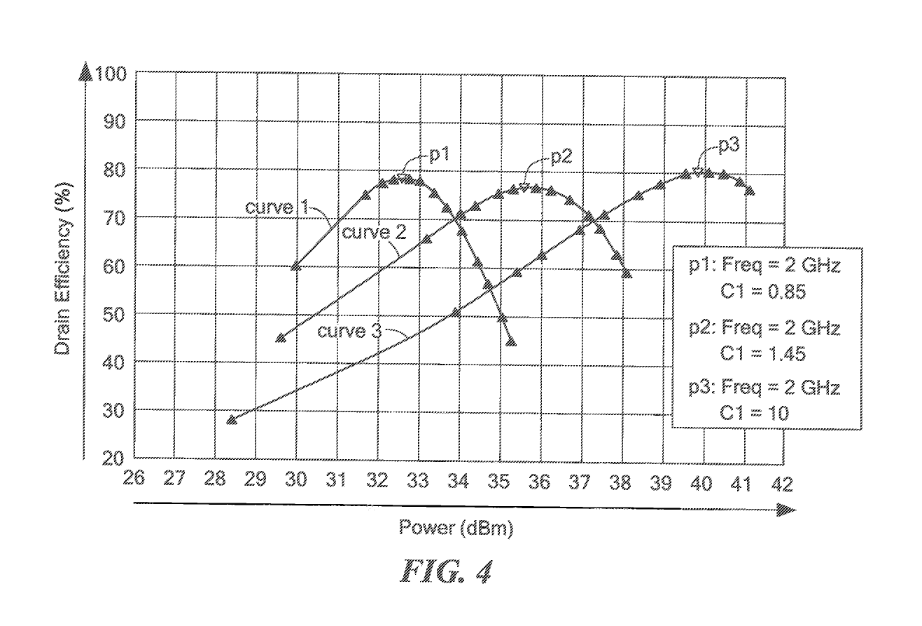

Referring now to FIG. 4 a plot of amplifier drain efficiency (Pₒᵤₜ/Pᵢₙ) versus output power (Pₒᵤₜ) has a horizontal axis with a scale in power ratio units of decibel-milliwatts (dBm) and a vertical axis with a scale in efficiency units of percent (%). The horizontal axis is representative of power levels of output signals (Pₒᵤₜ) (generated by an amplifier circuit, for example, which can be the same as or similar to amplifier circuit 30 of FIG. 3) in accordance with particular capacitance values (associated with a load modulation circuit, for example, which can be the same as or similar to load modulation circuit 22 of FIG. 1) and frequency of the amplifier input signal.

A drain efficiency of 70 percent (%) is shown achieved over a 10 dB dynamic range of output power (Pₒᵤₜ) at three different capacitance values (C1=0.85, 1.45, and 10 pF) in accordance with the concepts, systems, circuits and techniques sought to be protected herein, as illustrated by point p1, p2, and p3 on curves 1, 2, and 3, in one embodiment, the output power (Pₒᵤₜ) is varied by changing the pulse width of the amplifier input signal (i.e., a pulse signal). The pulse width of the amplifier input signal be adjusted by a pulse generator circuit, for example, which can be the same as or similar to pulse generator circuit 14 of FIG. 1.

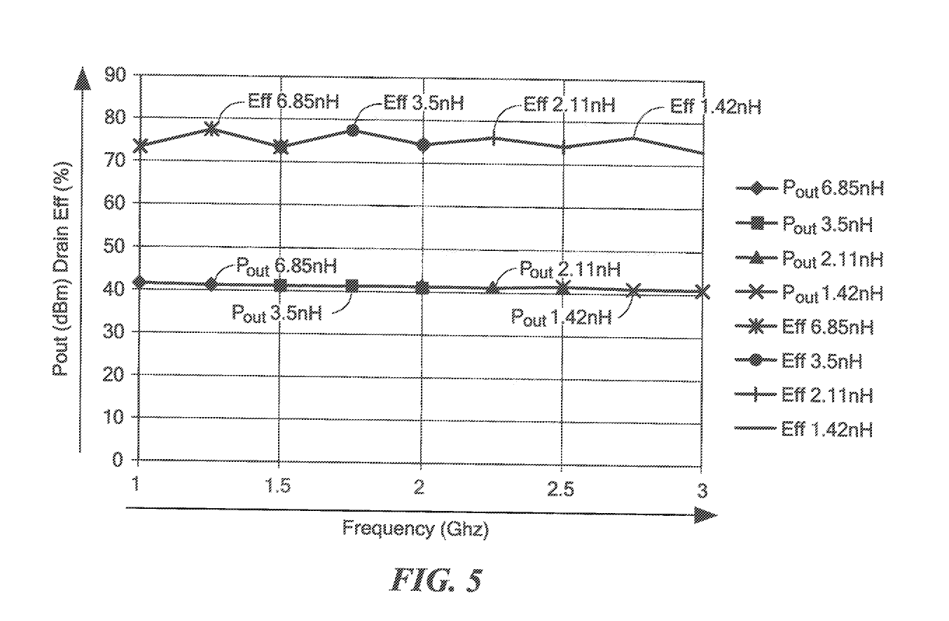

Referring now to FIG. 5 a plot of output power (Pₒᵤₜ) and drain efficiency (Pₒᵤₜ/Pᵢₙ) versus frequency has a horizontal axis with a scale in frequency units of Gigahertz (GHz) and a vertical axis with a scale in efficiency units of percent (%), The horizontal axis is representative of a frequency associated with an amplifier input signal received by an amplifier circuit (which can be the same as or similar to amplifier circuit 30 of FIG. 3). As is known in the art, RF amplifier circuit efficiency is generally related to frequency and power (Pᵢₙ) associated with the amplifier input signal, temperature, device geometry, intrinsic device characteristics, impedance matching between the amplifier circuit and a load, and the like.

In the plot, the output power (Pₒᵤₜ) and drain of efficiency(Pₒᵤₜ/Pᵢₙ) are shown for an amplifier circuit comprising at least one inductor tuning element and at least one capacitor one capacitor tuning element (which can be tuning elements L1, C1, C2 shown in FIG. 3). For purposes of illustration, the at least one capacitor has a fixed capacitance value of one-hundred picofarad (100 pF) while the inductor L1 is shown adjusted between four different inductance values (1.42 nanoHenry(nH), 2.11 nH, 3.5 nH, 6.85 nH) to allow the amplifier circuit to maintain greater than 70% drain efficiency for a frequency range of 1 GHz to 3 GHz, The output power (Pₒᵤₜ) is shown to be greater than 41 dBm across a frequency band (1-3 GHz) with flatness of ±0.3 dB, as indicated by Pₒᵤₜ 6.85 nH, Pₒᵤₜ 3.5 nH, Pₒᵤₜ 2.11 nH, Pₒᵤₜ 1.42 nH.

Having described preferred embodiments which serve to illustrate various concepts, circuits, and techniques which are the subject of this patent, it will now become apparent to those of ordinary skill in the art that other embodiments incorporating these concepts, circuits, and techniques may be used. For example, described herein is a specific example circuit topology and specific circuit implementation for achieving a desired performance. It is recognized, however, that the concepts and techniques described herein may be implemented using other circuit topologies and specific circuit implementations. Accordingly, it is submitted that that scope of the patent should not be limited to the described embodiments but rather should be limited only by the spirit and scope of the following claims.

What is claimed is:

1. A pulse width modulated/pulse modulated (PWM/PPM) power amplification circuit comprising:
a load modulation circuit coupled between an output of the amplification circuit and a load.

2. The power amplification circuit of claim 1 wherein said load modulation circuit comprises a transmission line and a capacitor circuit shunt coupled between said transmission line and a reference potential.

3. The power amplification circuit of claim 2 wherein said reference potential is ground.

4. The power amplification circuit of claim 3 wherein said capacitor circuit comprises at least one capacitor having a first terminal coupled to one end of said transmission line and a second terminal couple to said reference potential.

5. The power amplification circuit of claim 1 wherein said load modulation circuit comprises a plurality of capacitor elements switchably coupled such that in response to a control signal provided said load modulation circuit presents one of a plurality of different capacitance values at a terminal thereof.

6. The power amplification circuit of claim 2 wherein said capacitor circuit is provided as a variable capacitor capable having a capacitance value which changes in response to a control signal.

7. The power amplification circuit of claim 1 wherein said load modulation circuit comprises a plurality of series capacitors switchably coupled between the output of the amplification circuit and load, and a plurality of shunt inductors switchably coupled from the output of the amplification circuit to ground.

8. The power amplification circuit of claim 7 wherein said inductors are implemented with transmission lines.

9. The power amplification circuit of claim 7 wherein said plurality of series capacitors are implemented with a single variable capacitor having a capacitance value which changes in response to a control signal.

10. An amplifier circuit having an input and an output, the amplifier circuit comprising:
a pulse generator circuit having an input adapted to couple to the amplifier circuit input, said pulse generator circuit configured to receive a representative amplifier input signal at the pulse generator circuit input and substantially capable of implementing a pulse width modulation (PWM) scheme or a pulse position modulation (PPM) scheme and providing appropriately modulated analog signals at an output thereof;
a driver amplification circuit having an input coupled to the output of said pulse generator circuit and having an output;
an output amplification circuit having an input coupled to the output of said driver amplification circuit and having an output;
a reconstruction filter having an input coupled to the output of said output amplification circuit and having an output coupled to the output of the amplifying circuit, said reconstruction filter having a filter characteristic which provides appropriately filtered signals at an output thereof; and
a load modulation circuit coupled between the output of said reconstruction filter and the output of the amplifier circuit, said load modulation circuit having a selectable capacitance value wherein said load modulation circuit capacitance values are selected such that the amplifier circuit is capable of operation at power levels that exhibit a desired efficiency over a wide dynamic range of output powers.

11. The amplifier circuit of claim 10 wherein said load modulation circuit comprises a transmission line and a capacitor circuit shunt coupled between said transmission line and a reference potential.

12. The amplifier circuit of claim 11 wherein said reference potential is ground.

13. The amplifier circuit of claim 12 wherein said capacitor circuit comprises at least one capacitor having a first terminal coupled to one end of said transmission line and a second terminal couple to ground.

14. The amplifier circuit of claim 10 wherein said load modulation circuit comprises a plurality of capacitor elements switchably coupled such that in response to a control signal provided said load modulation circuit presents one of a plurality of different capacitance values at a terminal thereof.

15. The amplifier circuit of claim 10 wherein said capacitor circuit is provided as a variable capacitor capable having a capacitance value which changes in response to a control signal.

16. The amplifier circuit of claim 10 wherein the pulse generator circuit includes a digital to analog converter (DAC).

17. The amplifier circuit of claim 10 wherein:
said driver amplification circuit comprises a radio frequency (RF) amplifier having a relatively high gain characteristics; and
said output amplification circuit comprises an RF power amplifier (PA) having a relatively high power characteristic.

18. A method of operating a power amplification circuit, comprising;
coupling a load modulation circuit comprising a plurality of tuning elements between an output of the power amplification circuit and a load;
adjusting the plurality of tuning elements such that the power amplifier circuit is capable of operating at power levels that exhibit a desired efficiency over a wide dynamic range of output powers.

19. There method of claim 18 wherein adjusting the plurality of tuning elements comprises matching an output impedance associated with the power amplification circuit to an input impedance associated with the load.
